(19) United States
(12) Patent Application Publication
(10) Pub. No.: US 2025/0341582 A1
(43) Pub. Date: Nov. 6, 2025

(54) APPARATUS, SYSTEM AND METHOD FOR TESTING AN ELECTROCHEMICAL CELL UNDER A CONTROLLED TEMPERATURE CONDITION

(71) Applicant: LITENS AUTOMOTIVE PARTNERSHIP, Woodbridge (CA)

(72) Inventor: Sean KIERAN, Woodbridge (CA)

(21) Appl. No.: 18/865,099

(22) PCT Filed: Jun. 28, 2023
(86) PCT No.: PCT/CA2023/050892

§ 371 Date: Nov. 12, 2024

Related U.S. Application Data
(60) Provisional application No. 63/367,189, filed on Jun. 28, 2022.

(51) Int. Cl. G01R 31/374; G01R 31/385

(52) U.S. Cl. CPC G01R 31/374; G01R 31/385

(57) ABSTRACT

An apparatus is provided for testing an electrochemical cell under a controlled temperature condition. The apparatus comprises: a pair of terminals positioned to contact a pair of cell terminals; a cell-contacting member comprising a cell-contacting surface shaped to contact at least part of a cell casing when the pair of cell terminals contact the pair of terminals; a Peltier module comprising a cold side an a hot side, wherein the cold side is in contact with the cell-contacting member; and a heat sink member in contact with the hot side of the Peltier module. A system comprises the apparatus operatively connected to an electrical power supply, and a controller programmed to control a supply of electrical power from the electrical power supply to the Peltier module of the apparatus.

### CROSS-REFERENCE TO RELATED APPLICATION

This application claims priority to and the benefit of U.S. provisional patent application No. 63/367,189 filed on Jun. 28, 2022, the entire contents of which are incorporated by reference in this application, where permitted.

### FIELD OF THE DISCLOSURE

This disclosure relates to apparatuses, systems, and methods for testing an electrochemical cell under a controlled temperature condition.

### BACKGROUND OF THE DISCLOSURE

The performance characteristics (e.g., capacity, cycle life degradation, thermal power and gradient, and other characteristics) of electrochemical cells, such as those used in battery packs for electric vehicles, depend on their thermodynamic behaviour and on temperature conditions.

An electrochemical cell is conventionally tested by placing the cell in a thermal chamber, and subjecting the cell to an applied time-varying charge and/or discharge current in accordance with methods s such as the hybrid pulse power characterization (HPPC) test, galvanostatic intermittent titration technique (GITT), direct current internal resistance (DCIR) test, or drive cycle test. During testing, the electrochemical cell may generate significant amounts of heat in the thermal chamber.

This makes it difficult, if not impossible, to discern whether the cell's performance characteristics are attributable to the test program of charge and/or discharge current, or to temperature changes in the thermal cell. Further, the use of a thermal chamber does not permit control of temperature boundary conditions along the cell, such as a variable temperature profile along the length of the cell.

U.S. Pat. No. 8,901,892 B2 (Yazami et al.) discloses a system for thermodynamic evaluation of battery state of health, using a Peltier thermoelectric cooler or heater to establish thermodynamically stable electrochemical cell temperature conditions. In particular, Yamazi et al. discloses placing an end of a CR2016 coin cell directly on a Peltier plate, with the remainder of the cell exposed to the ambient environment. This approach may not adequately control the temperature of the entire cell, particularly for a cell having an elongate cylindrical or prismatic form as typically used in battery pack applications for electric vehicles.

### SUMMARY OF THE DISCLOSURE

In aspects, the present disclosure provides an apparatus, system and method for testing an electrochemical cell under a controlled temperature condition. Such apparatus, system and method may be useful when testing the electrochemical cell for performance characteristics, by maintaining the electrochemical cell in a substantially isothermal (i.e., constant temperature) state or other controlled temperature condition. It will be understood that the cell comprises a pair of cell terminals and a cell casing extending in a longitudinal direction between cell ends.

In one aspect, an apparatus of the present disclosure for testing an electrochemical cell comprises: a pair of terminals positioned to contact the pair of cell terminals; a cell-contacting member comprising a cell-contacting surface shaped to contact at least part of the cell casing when the pair of cell terminals contact the pair of terminals; at least one Peltier module comprising a cold side and a hot side, wherein the cold side is in contact with the cell-contacting member; and at least one heat sink member in contact with the hot side of the at least one Peltier module.

In an embodiment of the apparatus, the cell-contacting surface comprises at least a portion of concave cylindrical surface.

In an embodiment of the apparatus, the cell-contacting surface of the cell-contacting member surrounds the cell casing in a plane transverse to the longitudinal direction.

In an embodiment of the apparatus, the cell-contacting member comprises a plurality of cell-contacting member portions that are separable from each other.

In an embodiment of the apparatus, the cell-contacting member is made of a metal, which may be aluminum.

In an embodiment of the apparatus, the at least one Peltier module comprises a first plurality of Peltier modules spaced apart in a direction transverse to the longitudinal direction.

In an embodiment of the apparatus, the at least one Peltier module comprises a second plurality of Peltier modules spaced apart in the longitudinal direction.

In an embodiment of the apparatus, the at least one heat sink member comprises a plurality of fins.

In an embodiment of the apparatus, the at least one heat sink member comprises a plurality of heat sink members.

In an embodiment of the apparatus, the apparatus further comprises at least one electrical fan oriented to create an air flow across the at least one heat sink member.

In an embodiment of the apparatus, the cell-contacting member comprises a cell-contacting member first portion comprising a cell-contacting surface first portion, and a cell-contacting member second portion comprising a cell-contacting surface second portion. The cell-contacting member first portion is slidably attached to the cell-contacting member second portion to allow a distance between the cell-contacting surface first portion and the cell-contacting surface second portion to be varied. In such embodiment the apparatus may further comprise at least one linear actuator having an actuator first end attached to the cell-contacting member first portion and an actuator second end attached to the cell-contacting member second portion. The linear actuator is extendible between the actuator first end and the actuator second end to vary the distance between the cell-contacting surface first portion and the cell-contacting surface second portion.

In an embodiment of the apparatus, the apparatus further comprises at least one temperature sensor positioned to measure a temperature of the cell when the pair of cell terminals contact the pair of terminals.

In one embodiment of the apparatus, the apparatus further comprises at least one heat flux sensor positioned to measure a heat flux of the cell when the pair of cell terminals contact the pair of terminals.

In another aspect, a system of the present disclosure for testing an electrochemical cell comprises: an apparatus according any of the embodiments as described herein; at least one electrical power supply operatively connected to the at least one Peltier module of the apparatus; and a controller operatively connected to the electrical power supply, and comprising a processor and a memory comprising a non-transitory computer readable medium storing instructions executable by the processor to control a supply of electrical power from the at least one electrical power supply to the at least one Peltier module of the apparatus.

In an embodiment of the system, the at least one Peltier module of the apparatus comprises a first Peltier module and a second Peltier module spaced apart from the first Peltier module in the longitudinal direction of the cell. The instructions are executable by the processor to control the supply of electrical power from the at least one electrical power supply to the first Peltier module, independently of the supply of electrical power from the at least one electrical power supply to the second Peltier module.

In an embodiment of the system, the apparatus comprises a temperature sensor positioned to measure a temperature of the cell and/or a heat flux sensor to measure a heat flux of the cell. The instructions are executable by the processor to control the supply of electrical power from the at least one electrical power supply to the at least one Peltier module of the apparatus based on the temperature of the cell measured by the temperature sensor and/or the heat flux of the cell measured by the heat flux sensor.

### BRIEF DESCRIPTION OF THE DRAWINGS

For a better understanding of the embodiment(s) described herein and to show more clearly how the embodiment(s) may be carried into effect, reference will now be made, by way of example only, to the accompanying drawings.

FIG. 1 shows a perspective view of an embodiment of a prior art electrochemical cell for which the apparatus of the present disclosure may be used.

FIGS. 2 and 3 show a top-front perspective view (FIG. 2) and a bottom-rear perspective view (FIG. 3) of an embodiment of an apparatus of the present disclosure.

FIGS. 4 and 5 show a top-front perspective view (FIG. 4) and a bottom-front perspective view (FIG. 5) of a cell holder subassembly of the apparatus of FIG. 2.

FIGS. 6 and 7 show a top-front perspective view (FIG. 6) and a top-rear perspective view (FIG. 7) of a cell holder subassembly of FIG. 4, with the cell-contacting member upper portion thereof removed.

FIG. 8 shows a bottom-front perspective view of a cell-contacting member upper portion of the cell holder subassembly of FIG. 4.

FIG. 9 shows a top-front perspective view of the cell holder subassembly of FIG. 4, with the cell-contacting member upper portion thereof removed, and containing a cell.

FIGS. 10 and 11 show a top-front perspective view (FIG. 10) and a bottom-front perspective view (FIG. 11) of an embodiment of an insulation subassembly of the apparatus of FIG. 2.

FIG. 12 shows a top-front perspective view of a housing lower portion of the insulation subassembly of FIG. 10, with the cell-contacting member lower portion and a cell installed therein.

FIG. 13 shows a bottom-front perspective view of a housing upper portion of the insulation subassembly of FIG. 10, with the cell-contacting member upper portion installed therein.

FIG. 14 shows a top-front perspective view of the lower heat sink subassembly of the apparatus of FIG. 2.

FIG. 15 shows a bottom-front perspective view of the upper heat sink subassembly of the apparatus of FIG. 2.

FIG. 16 shows a top-front perspective view of the lower heat sink subassembly of FIG. 14 with the front fan assembly thereof removed.

FIG. 17 shows a bottom-front perspective view of the upper heat sink subassembly of FIG. 15 with the front fan assembly thereof removed.

FIG. 18 shows a medial sectional view of a portion of the apparatus of FIG. 2 at an interface of the cell holder subassembly, insulation subassembly, lower heat sink assembly and upper heat sink assembly.

FIG. 19 shows a medial sectional view of a portion of an alternative embodiment of an apparatus of the present disclosure, at an interface of the cell holder subassembly, insulation subassembly, lower heat sink assembly and upper heat sink assembly.

FIG. 20 is a functional block diagram of an embodiment of a system of the present disclosure.

### DETAILED DESCRIPTION OF THE DISCLOSURE

### Electrochemical Cell

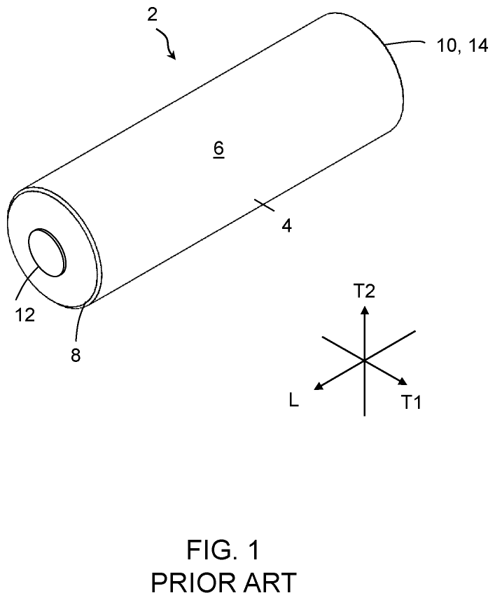

FIG. 1 shows an embodiment of a prior art electrochemical cell 2 (hereinafter simply referred to as a cell) for which the apparatus of the present disclosure may be used. In this embodiment, the cell 2 has a cylindrical cell body 4 having a cell casing 6 that extends in a longitudinal direction defined between a cell first end 8 and a cell second end 10. For reference, FIG. 1 shows a set of three mutually orthogonal axes to denote a longitudinal direction (L), and exemplary transverse directions (T1 and T2). In this embodiment, the cell 2 has a pair of cell terminals—i.e., a cell positive terminal 12 at the cell first end 8, and a cell negative terminal 14 at the cell second end 10. In other embodiments (not shown), the cell 2 may have different geometries and terminal configurations. For example, the cell 2 may have a rectangular prismatic shape. As another example, the cell positive terminal 12 and the cell negative terminal 14 may be disposed at the cell first end 8, with the cell negative terminal 14 forming a peripheral portion of the cell first end 8.

### Apparatus

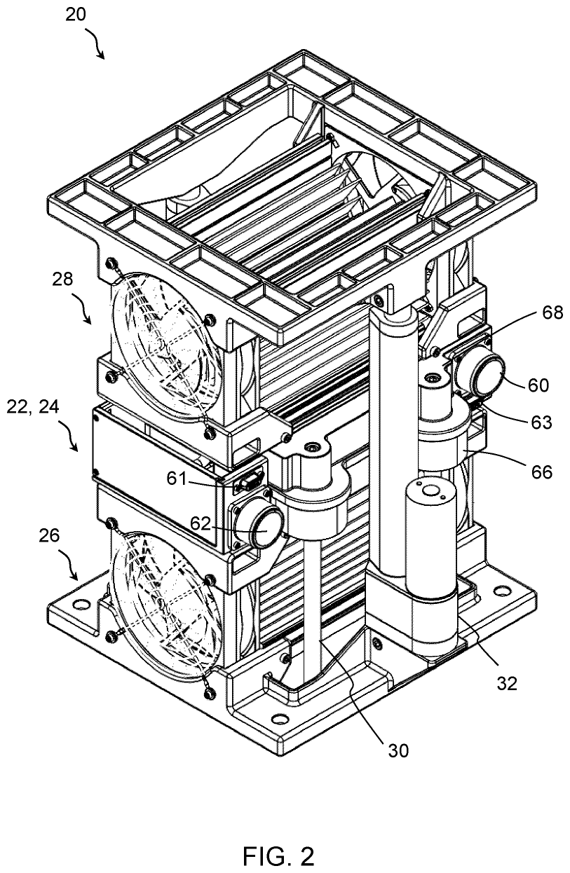

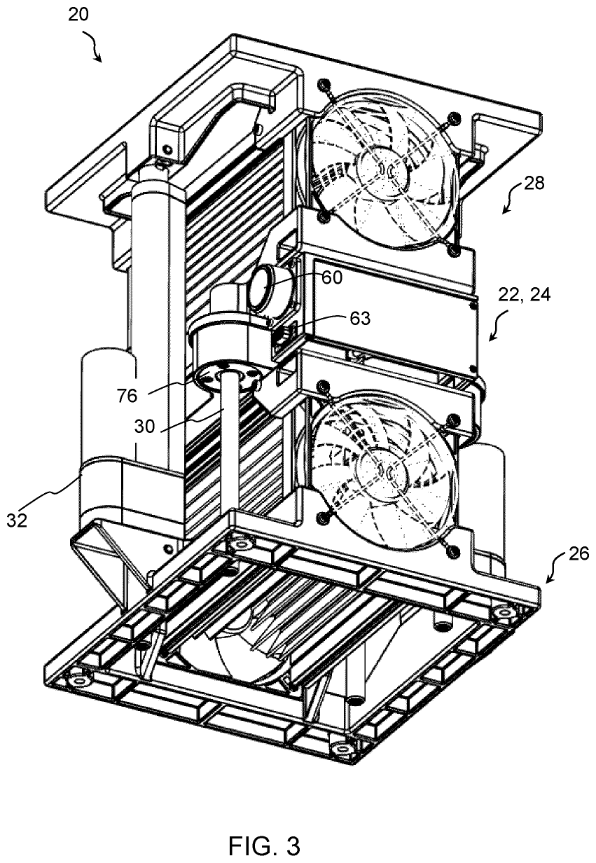

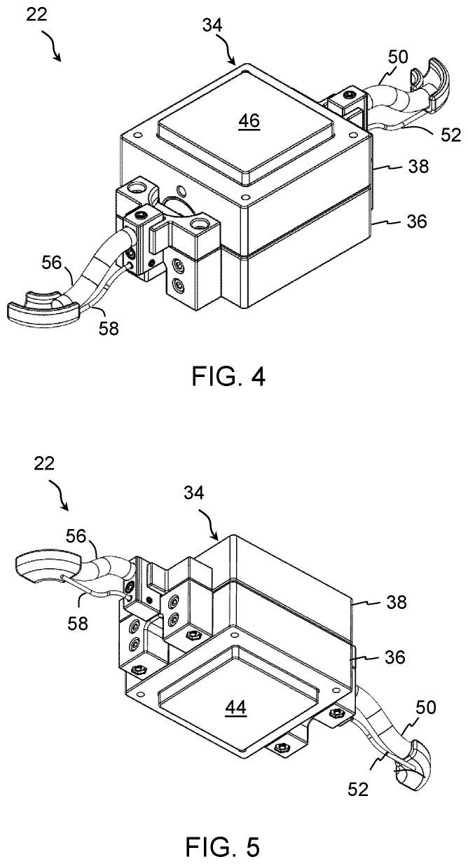

FIGS. 2 and 3 show top-front and bottom-rear perspective views, respectively, of an embodiment of an apparatus 20 of the present disclosure. The apparatus 20 includes a cell holder subassembly 22, an insulation subassembly 24, a lower heat sink subassembly 26, and a upper heat sink subassembly 28. The cell holder subassembly 22 (FIG. 4) is disposed within the insulation subassembly and thus concealed from view in FIGS. 2 and 3. It will be understood that different parts of the apparatus 20 identified herein using the terms “lower” and “upper” may instead be identified using the terms “first” and “second”, respectively. The subassemblies 22, 24, 26, 28 of the apparatus 20 are further described below.

### Cell Holder Subassembly

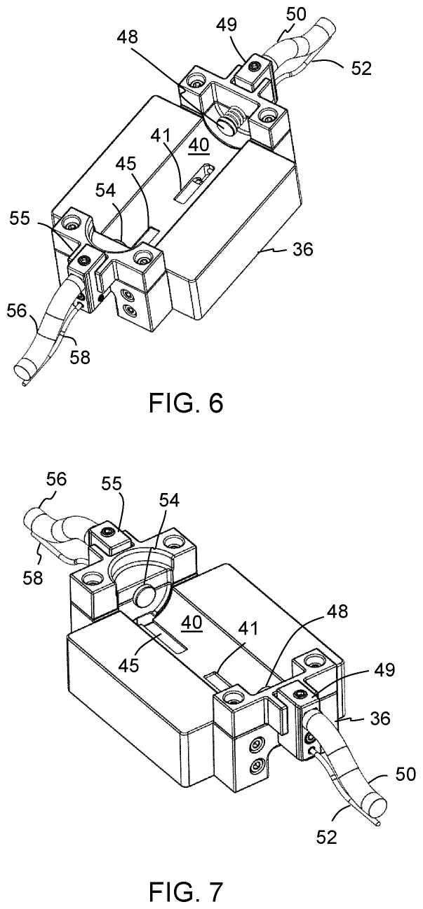

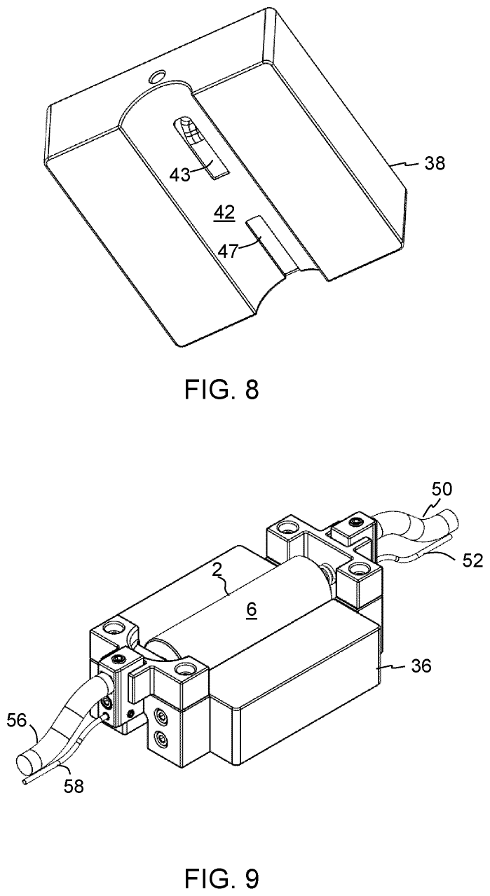

FIGS. 4 and 5 show a top-front perspective view and a top-rear perspective view, respectively, of the cell holder subassembly 22. In this embodiment, the cell holder subassembly 22 includes a cell-contacting member 34 with a cell-contacting surface 40, 42 (FIGS. 6 and 8) for contacting at least part of the cell casing 6 (FIG. 1), and thus conducting heat away from the cell 2. The cell-contacting member 34 may be formed from a material with relatively high thermal conductivity, such as a metal, and more particularly an aluminum alloy (e.g., grade 6061-T6 aluminum alloy).

In this embodiment, the cell-contacting member 34 includes a cell-contacting member lower portion 36 (as shown separately in FIGS. 6, 7 and 9), and a cell-contacting member upper portion 38 (as shown separately in FIG. 8). The cell-contacting member lower portion 36 and the cell-contacting-member upper portion 38 define a cell-contacting surface lower portion 40 and cell-contacting surface upper portion 42, respectively. The cell-contacting surface lower portion 40 and cell-contacting surface upper portion 42 are concave semi-cylindrical surfaces that are complementary in shape to the convex cylindrical surface of the cell casing 6 (FIG. 1). Thus, the cell-contacting surface lower portion 40 and cell-contacting surface upper portion 42 contact the cell casing 6 and surround the cell casing 6 in a plane transverse to the longitudinal direction of the cell 2, when the cell 2 is placed inside the cell-contacting member 34 (see FIG. 9).

Referring to FIGS. 4 and 5, the cell-contacting member lower portion 36 and the cell-contacting-member upper portion 38 define a lower Peltier module-contacting surface 44 (FIG. 5) and an upper Peltier module-contacting surface 46 (FIG. 4), respectively. The lower Peltier module-contacting surface 44 and the upper Peltier module-contacting surface 46 are used to contact the cold sides of Peltier modules 86 and 106 of the lower heat sink assembly 26 and the upper heat sink assembly 28, respectively, as described below.

In other embodiments, the cell-contacting member may be formed by a single part or a greater number of parts. The cell-contacting member may partially or completely surround the cell casing. The cell-contacting member may have one or more cell-surfaces of different shapes than cylindrical so as to conform to the shape of the cell casing.

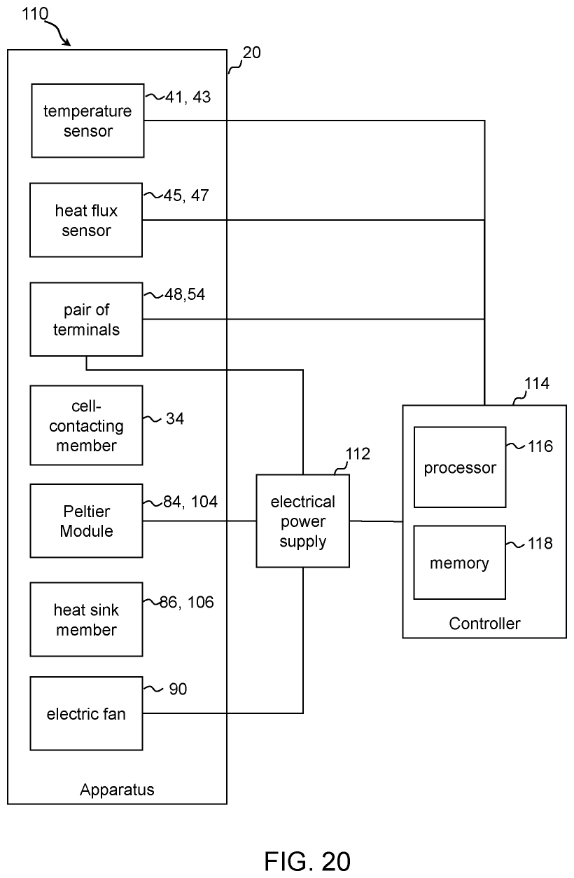

Referring to FIGS. 6 and 7, the cell holder subassembly 22 also includes a pair of terminals 48, 54 for contacting the pair of terminals of the cell 2 when the cell 2 is in contact with the cell-contacting surfaces 40 and 42. In this embodiment, a spring-biased positive terminal 48 is provided for contacting the cell positive terminal 12 (FIG. 1), and is conductively connected via a terminal block 49 to a positive lead 50 (e.g., American wire gage (AWG) 8). A negative terminal 54 is provided for contacting the cell negative terminal 14 (FIG. 1), and is conductively connected via a terminal block 55 to a negative lead 56. The positive lead 50 and the negative lead 56 are conductively connected to an electrical power supply 112 (FIG. 20). Accordingly, electrical current may be charged to and/or discharged from the cell 2 via the terminals 48, 54 for testing the cell 2.

The positive terminal 48 and the negative terminal 54 are also connected via the terminal block 49 and 55, respectively, to wires 52 and 58 (e.g., American wire gage (AWG) 22), respectively. The wires 52 and 58 are connected to a controller 114 (FIG. 20) that serves as a data acquisition unit for monitoring and/or measuring the voltage of the cell 2 during testing.

In this embodiment, the cell holder subassembly 22 also includes at least one temperature sensor positioned to measure a temperature of the cell 2. In one embodiment, the at least one temperature sensor may comprise a resistance temperature detector (RTD) (also referred to as a resistance thermometer). In other embodiments, other types of temperature sensors may be used with non-limiting examples including thermistors, and silicon bandgap temperature sensors. Referring to FIGS. 6 and 8, in this embodiment, a lower temperature sensor 41 is disposed in a recess formed in the cell-contacting member lower portion 36 and extending downwardly from the cell-contacting surface lower portion 40, such that the lower temperature sensor 41 is disposed immediately below the cell casing 12, when the cell 2 is positioned between the terminals 48, 54. An upper temperature sensor 43 is disposed in a recess formed in the cell-contacting member upper portion 38 and extending upwardly from the cell-contacting surface upper portion 42, such that the upper temperature sensor 43 is disposed immediately above the cell casing 12, when the cell 2 is positioned between the terminals 48, 54. The lower temperature sensor 41 and the upper temperature sensor 43 may be secured to the cell-contacting member lower portion 36 and cell-contacting member upper portion 38, respectively, using an adhesive potting compound or other means. The temperature sensors 41, 43 are operatively connected (e.g., via DB9 connectors 61 and 63 (FIGS. 2 and 3)), to the controller 114 (FIG. 20) that serves as a data acquisition unit for monitoring and/or measuring the temperature of the cell 2 during testing.

In this embodiment, the cell holder subassembly 22 also includes at least one heat flux sensor (also referred to as heat flux transducers, heat flux gauges) positioned to measure a rate of heat flux per unit area of the cell 2. Heat flux sensors are known in the art and do not by themselves constitute part of the invention. In general, a heat flux sensor is a transducer that generates an electrical signal that can be correlated to a heat rate applied to the surface of the heat flux sensor. Referring to FIGS. 6 and 8, in this embodiment, a lower heat flux sensor 45 is disposed in a recess formed in the cell-contacting member lower portion 36 and extending downwardly from the cell-contacting surface lower portion 40, such that the lower heat flux sensor 45 is disposed immediately below the cell casing 12, when the cell 2 is positioned between the terminals 48, 54. An upper heat flux sensor 47 is disposed in a recess formed in the cell-contacting member upper portion 38 and extending upwardly from the cell-contacting surface upper portion 42, such that the upper heat flux sensor 47 is disposed immediately above the cell casing 12, when the cell 2 is positioned between the terminals 48, 54. The lower heat flux sensor 45 and the upper heat flux sensor 47 may be secured to the cell-contacting member lower portion 36 and cell-contacting member upper portion 38, respectively, using an adhesive potting compound or other means. The at least one heat flux sensors 45, 47 are operatively connected, such as via DB9 connectors 61 and 63 (FIGS. 2 and 3), to the controller 114 (FIG. 20) that serves as a data acquisition unit for monitoring and/or measuring the heat flux from the cell 2 during testing.

### Insulation Subassembly

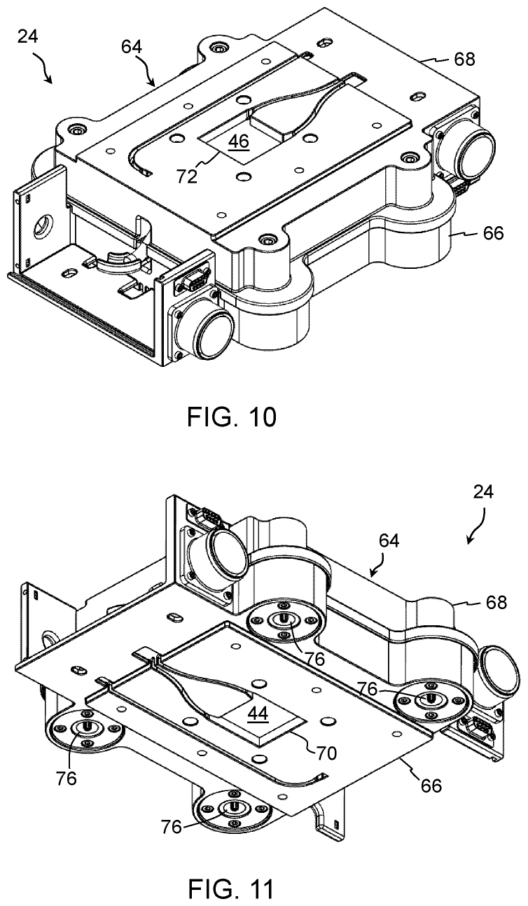

FIGS. 10 and 11 show a top-front perspective view and a bottom-front perspective view, respectively, of the insulation subassembly 24. In this embodiment, the insulation subassembly 24 includes a housing 64 that contains the cell holder assembly 22. The housing 64 may be made of a material with relatively lower thermal conductivity than the cell holder subassembly 22, such as plastic, and more particularly, a nylon plastic (e.g., polyamide nylon PA2200, suitable for 3D printing).

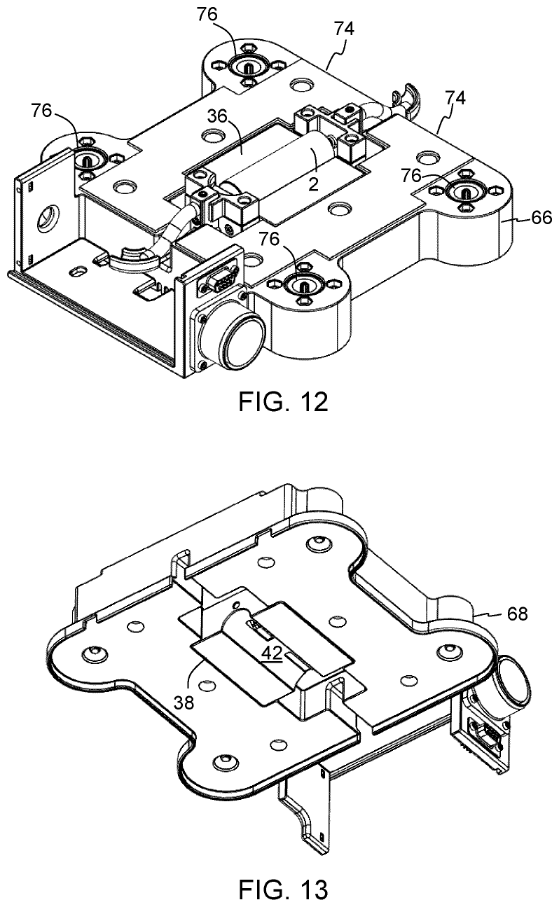

In this embodiment, the housing 64 includes a housing lower portion 66 and a housing upper portion 68. Referring to FIG. 12, the housing lower portion 66 defines a recess that receives the cell-contacting member lower portion 36, which is attached to the housing lower portion 66 by socket head screws. Referring to FIG. 13, the housing upper portion 68 defines a recess that receives the cell-contacting member upper portion 38, which is attached to the housing upper portion 68 by socket head screws.

In this embodiment, referring to FIGS. 10 and 11, the housing lower portion 66 and the housing upper portion 68 define a lower aperture 70 and an upper aperture 72, respectively, that expose the lower Peltier module-contacting surface 44 and the upper Peltier module-contacting surface 46, respectively of the cell holder subassembly 22.

In this embodiment, referring to FIG. 12, a pair of thin (e.g., 1/16″) neoprene foam sheets 74 (e.g., model no. 93375K427; McMaster-Carr Supply Company; Elmhurst, Illinois, USA) are disposed between the housing lower portion 66 and the housing upper portion 68. The foam sheets 74 (FIG. 12) allow for some tolerance in the mating and alignment of the housing lower portion 66 and the housing upper portion 68, by helping to close any air gap that might exist between these parts so as to better insulate the cell 2.

### Bottom and Upper Heat Sink Subassemblies

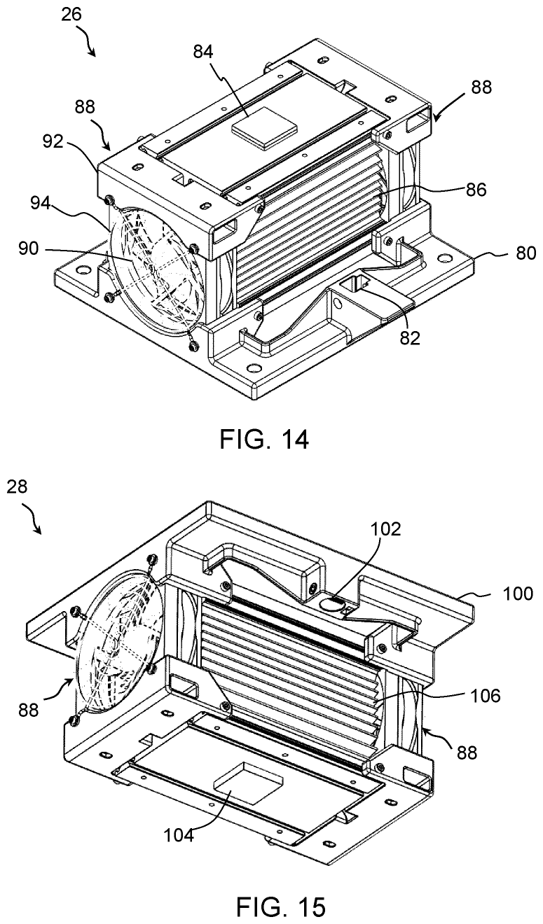

FIG. 14 shows a top-front perspective view of the lower heat sink subassembly 26, and FIG. 15 shows a bottom-front perspective view of the upper heat sink subassembly 28. In this embodiment, the lower heat sink subassembly 26 and the upper heat sink subassembly 28 are substantially similar to each other.

In this embodiment, the lower heat sink assembly 26 and the upper heat sink assembly 28 includes a bracket 80 and 100, respectively, to which other parts of the lower heat sink assembly 26 and the upper heat sink assembly 28, respectively, are attached by socket head screws. The bracket 80 and bracket 100 define sockets 82 and 102, respectively, which receive opposite actuator ends of linear actuators 32 (FIGS. 2 and 3). The bracket 80 also supports the apparatus 20 as a whole.

In this embodiment, each of the lower heat sink assembly 26 and the upper heat sink assembly 28 includes a Peltier module 84 and 104, respectively. Peltier modules (also referred to as Peltier devices, Peltier heat pumps, or thermoelectric coolers (TEC)) are known in the art and do not by themselves constitute the present invention. In general, a Peltier module includes doped semi-conductor materials that are arranged and electrically interconnected such that an applied voltage causes a temperature difference between a “hot side” and a “cold side” of the Peltier module. The terms “hot side” and “cold side” are used to nominally differentiate between the two sides of the Peltier device, and do not limit the invention by any particular temperature; in use, the hot side may be at a higher temperature or a lower temperature than the cold side.

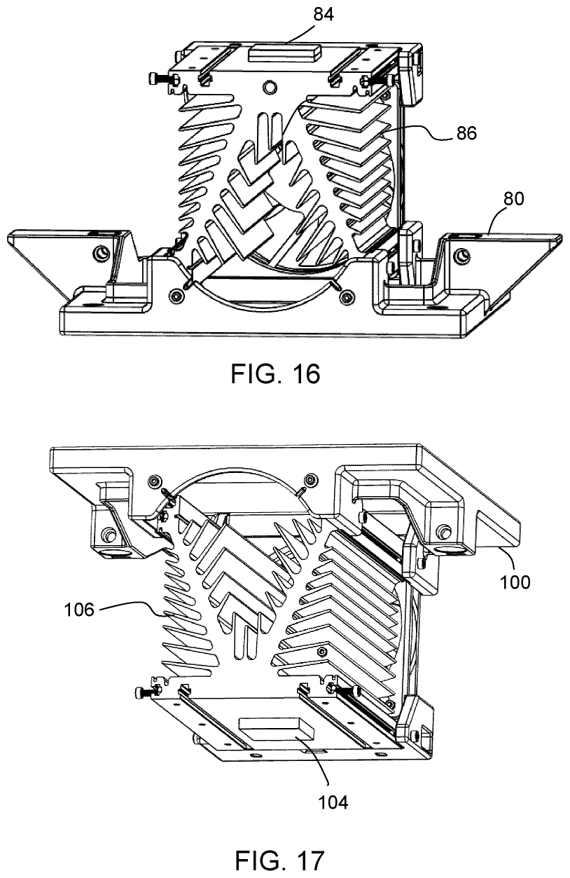

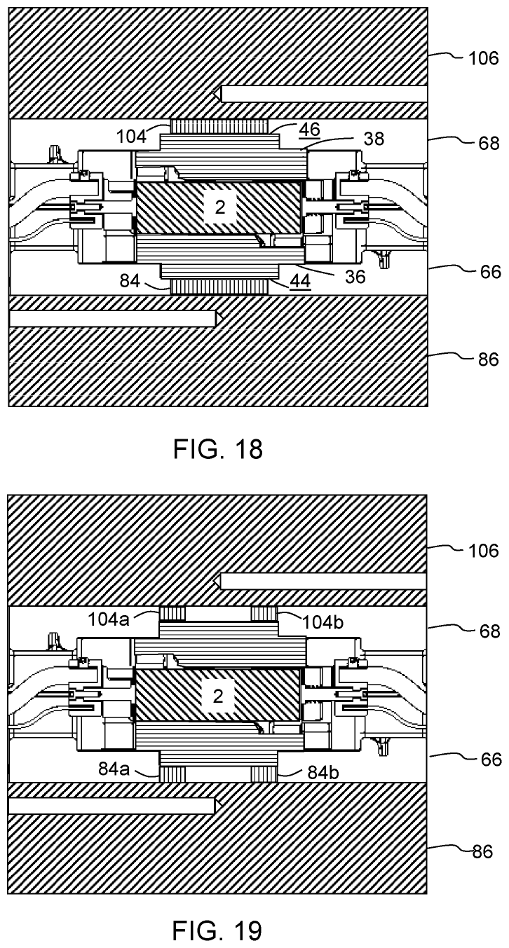

In this embodiment, each of the lower heat sink assembly 26 and the upper heat sink assembly 28 includes a heat sink member 86 and 106, respectively. Referring to FIGS. 16 and 17, each of the heat sink members 86 and 106 is an extruded aluminum member having a V-shaped configuration of two branches with fins extending therefrom in a pinnate form (e.g., heatsink model no. 392-300AB; Wakefield Thermal Solutions, Inc., Nashua, New Hampshire, USA). In other embodiments, the heat sink member 86 and 106 may have different shapes and be made of different materials. For example, each of the heat sink member may comprise a fin stack, or in a simplest case, a block of material.

Each of the Peltier modules 84 and 104 is operatively connected to an conductively connected to an electrical power source such as via 8-pin female connectors 60 and 62, respectively (FIG. 2). Accordingly, electrical power may be supplied to the Peltier modules 84 and 104 to activate their heat pump effect while testing the cell 2.

Each of the Peltier modules 84 and 104 is attached to the heat sink member 86 and 106, respectively (e.g., by an adhesive potting compound or other means) so that the hot side of the Peltier module 84 and 104 is in contact with the heat sink member 86 and 106, respectively.

FIG. 18 shows a medial sectional view of a portion of the apparatus 20. The Peltier modules 84 and 104 project through the lower aperture 70 and upper aperture 72 (FIGS. 10 and 11), respectively, of the housing lower portion 64 and the housing upper portion 66, respectively, such that the cold sides of the Peltier modules 84 and 104 contact the lower Peltier module-contacting surface 44 and the upper Peltier module-contacting surface 46, respectively. Accordingly, in use, heat generated by the cell 2 transfers conductively from the cell casing 6 to the heat sink members 86 and 106 via the cell-contacting member lower and upper portion 36 and 38, respectively, and the Peltier modules 84 and 104, respectively, assisted by the active heat pump effect of the Peltier modules 84 and 104 when energized.

FIG. 19 shows a medial sectional view of a portion of an alternative embodiment of an apparatus 20 that is similar to the embodiment shown in FIG. 18 except that the lower heat sink subassembly 26 and has a plurality of Peltier modules 84a and 84b spaced apart along the longitudinal direction of the cell 2, and the upper heat sink subassembly 28 and has a plurality of Peltier modules 104a and 104b spaced apart along the longitudinal direction of the cell 2. The Peltier modules 84a, 104a may be separately connected to an electrical power source separately from Peltier modules 84b and 104b so as to provide differential active heat pump effects between them. By controlling the Peltier modules 84a and 104a independently of controlling the Peltier modules 84b and 106b, it is possible to effect a temperature gradient along the cell 2 in its longitudinal direction.

Referring again to FIGS. 14 and 15, in this embodiment, each of the lower heat sink subassembly 26 and the upper heat sink subassembly 28 includes a pair of fan assemblies 88, with a first fan assembly 88 being disposed at the front of the heat sink member 86 or 106, and a second fan assembly 88 being disposed at the rear of the heat sink member. Each fan assembly 88 includes an electric fan 90, a fan bracket 82 and a fan guard 94. The fan assembly 88 is connected at one end to the bracket 80 or 100, and connected at the other end to the fan bracket 92, which is in turn connected to the heat sink member 86 or 106. The fan 90 is oriented to direct air flow through the heat sink member 86 or 106, to assist with the cooling effect of the Peltier modules 84 or 104 on the cell 2. In the embodiment shown, the fan 90 is implemented using a 12 volt case fan, as is typically used for cooling of personal computers.

### Open and Closed Configurations of Apparatus

FIGS. 2 and 3 show the apparatus 20 in a closed configuration for testing a cell 2, in which the upper heat sink subassembly 28, the attached housing upper portion 68, and the attached cell-contacting member upper portion 38 are in a lowered position such that the cell-contacting surface upper portion 42 mates with the cell casing 12, such that the cell 2 is in contact with the cell-contacting surface lower portion 40 and the cell-contacting surface upper portion 42 and enclosed therebetween.

The apparatus 20 may be also be placed in a open configuration for loading or removing the cell 2. In the open configuration, the upper heat sink subassembly 28, the attached housing upper portion 68, and the attached cell-contacting member upper portion 38 are in a raised position such that the cell-contacting member upper portion 38 is disposed further above the cell-contacting member lower portion 36.

In this regard, four shafts 30 having internally threaded surfaces are attached to the housing upper portion 68 of the insulation subassembly 24 by externally threaded socket head screws. Referring to FIGS. 3, 11 and 12, four flange-mounted linear ball bearing assemblies 76 (e.g., model no. 6483K53; McMaster-Carr Supply Company; Elmhurst, Illinois, USA) are attached to the housing lower portion 66 of the insulation subassembly 24. Each of the linear ball bearing assemblies 76 slidably receives one of the four shafts 30. Accordingly, the shafts 30 along with the attached housing upper portion 68 and cell-contacting member upper portion 38 may travel upwardly relative to the cell-contacting member lower portion 36. As previously described, a pair of electrically powered, force feedback linear actuators 32 (e.g., model no., FA-PO-150-12-6 (TM); E-Motion Inc.; Eugene, Oregon, USA) are attached at their opposite actuator ends to the lower heat sink subassembly 26 and the upper heat sink subassembly 28. The linear actuators 32 may be equipped with potentiometers for force feedback. The linear actuators 32 can extend upwardly to raise the upper heat sink subassembly 28, the attached housing upper portion 68 and the attached cell-contacting member upper portion 38 relative to the cell-contacting member lower portion 36, to place the apparatus in the open configuration. The cell 2 may then be removed from or placed onto the cell-contacting surface lower portion 40.

The linear actuators 32 can then retract downwardly to lower the cell-contacting member upper portion 38 so that the cell-contacting surface upper portion 42 contacts the cell casing 6. As a result of the retracting of the linear actuator 32, the cell-contacting member upper portion 38 contacts the cell casing 12, but applies a negligible (effectively zero) compressive force to the cell 2 to avoid damaging the cell 2.

### System

FIG. 20 is a functional block diagram of an embodiment of a system 110 of the present disclosure, including an apparatus 20 of the present disclosure operatively connected to an electrical power supply 112 and a controller 114. Lines between components in the functional block diagram indicate operative connections between them. Although the components of the functional block diagram are illustrated with singular blocks and labelled with terms in the singular, it will be understood that each block may be implemented by one or more physically discrete, operatively connected components.

The electrical power supply 112 is operatively connected to the pair of terminals 48 and 54 to provide charge and/or discharge currents to them for testing the cell 2. The electrical power supply 112 is also operatively connected to the Peltier modules 84 and 104, and the fan 90 of the fan assemblies 90 to provide electric power to them.

The controller 114 includes a processor 116 and a memory. “Processor”, as used herein, refers to one or more electronic devices that is/are capable of reading and executing instructions stored on a memory to perform operations on data, which may be stored on a memory or provided in a data signal. Non-limiting examples of processors include devices referred to as microprocessors, microcontrollers, microcontroller units (MCU), central processing units (CPU), digital signal processors, and field programmable gate arrays (FPGAs). “Memory”, as used herein, refers to a non-transitory tangible computer-readable medium for storing information in a format readable by a processor, and/or instructions readable by a processor to implement an algorithm. Non-limiting types of memory include solid-state, optical, and magnetic computer readable media. Memory may be non-volatile or volatile. Instructions stored by a memory may be based on a plurality of programming languages known in the art, with non-limiting examples including the C, C++, Python™, MATLAB™, and Java™ programming languages.

The processor 116 is operatively connected to the pair of terminals 48 and 58 to acquire voltage information during the charging and discharging of the cell 2. The processor 116 is operatively connected to the temperature sensors 41 and 43 to acquire data indicative of the temperature of the cell 2. The processor 116 is operatively connected to the heat flux sensors 45 and 47 to acquire data indicative of the heat flux per unit area emitted by the cell 2. The processor 116 is operatively connected to the electric power supply 112 to control the supply of electric power to operatively connected components. The memory 118 stores instructions that are executable by the processor 116 to control the supply of electrical power from the electrical power supply 112 to any one or a combination of the terminals 48 and 54, the Peltier modules 84 and 104 (or 84a, 84b, 104a, and 104b in respect to the embodiment shown in FIG. 19), and the electric fans 90. The instructions may govern the control of the supply of electrical power to any one or a combination of the terminals 48 and 54, the Peltier modules 84 and 104 and the electric fans 90 in response to data acquired from any one or a combination of the pair of terminals 48 and 53 (i.e., in relation to voltage, current or other parameters), temperature sensors 41 and 43 (i.e., in relation to temperature of the cell 2), and the heat flux sensors 45 and 45 (i.e., in relation to heat flux of the cell 2). As a non-limiting example, the instructions may implement a routine that involves steps of: controlling electric power supply from the electrical power supply 112 to the terminals 48 and 54 to conduct a performance characterization test on the cell 2; measuring either a temperature of the cell 2 using the temperature sensors 41 and 43, or a heat flux from the cell 2 using the heat flux sensors 45 and 47, or both; and controlling a temperature condition of the cell by controlling electric power supply from the electrical power supply 112 to the Peltier modules 84 and 104 based on the measured temperature data or the measured heat flux data or both. The controller 114 may implement a PID (proportional-integral-derivative) control algorithm using the measured temperature and/or measured heat flux as feedback process value(s) to achieve a desired setpoint temperature condition. As a non-limiting example, the setpoint temperature condition may be an isothermal temperature condition defined by a setpoint temperature condition for the cell 2. As a non-limiting example, with reference to the embodiment of FIG. 19, the setpoint temperature condition may be a temperature gradient along the length of the cell 2, achieved by the controller 114 controlling the Peltier modules 84a, 104a independently of the Peltier modules 84b, 104b.

### Interpretation

For simplicity and clarity of illustration, where considered appropriate, reference numerals may be repeated among the Figures to indicate corresponding or analogous elements. In addition, numerous specific details are set forth in order to provide a thorough understanding of the embodiment or embodiments described herein. However, it will be understood by those of ordinary skill in the art that the embodiments described herein may be practiced without these specific details. In other instances, well-known methods, procedures and components have not been described in detail so as not to obscure the embodiments described herein. It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Various terms used throughout the present description may be read and understood as follows, unless the context indicates otherwise: “or” as used throughout is inclusive, as though written “and/or”; singular articles and pronouns as used throughout include their plural forms, and vice versa; similarly, gendered pronouns include their counterpart pronouns so that pronouns should not be understood as limiting anything described herein to use, implementation, performance, etc. by a single gender; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

The indefinite article “a” is not intended to be limited to mean “one” of an element. It is intended to mean “one or more” of an element, where applicable, (i.e. unless in the context it would be obvious that only one of the element would be suitable).

Any reference to upper, lower, top, bottom or the like are intended to refer to an orientation of a particular element during use of the claimed subject matter and not necessarily to its orientation during shipping or manufacture. The upper surface of an element, for example, can still be considered its upper surface even when the element is lying on its side.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

As used in this document, “attached” in describing the relationship between two connected parts includes the case in which the two connected parts are “directly attached” with the two connected parts being in contact with each other, and the case in which the connected parts are “indirectly attached” and not in contact with each other, but connected by one or more intervening other part(s) between.

Aspects of the present invention may be described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor, such that the processor, and a memory storing the instructions, which execute via the processor, collectively constitute a machine for implementing the functions/acts specified in the flowchart and/or block diagram block or blocks.

The flowcharts and functional block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The embodiments of the inventions described herein are exemplary (e.g., in terms of materials, shapes, dimensions, and constructional details) and do not limit by the claims appended hereto and any amendments made thereto. Persons skilled in the art will appreciate that there are yet more alternative implementations and modifications possible, and that the following examples are only illustrations of one or more implementations. The scope of the invention, therefore, is only to be limited by the claims appended hereto and any amendments made thereto.

### PARTS LIST

| Reference | | |
|---|---|---|
| character | FIG. | Description |
| 2 | 1 | electrochemical cell (cell) |
| 4 | 1 | cell: body |
| 6 | 1 | cell: casing |
| 8 | 1 | cell: first end |
| 10 | 1 | cell: second end |
| 12 | 1 | cell: positive terminal |
| 14 | 1 | cell: negative terminal |
| 20 | 2 | apparatus |
| 22 | 4 | apparatus: cell holder subassembly |
| 24 | 10 | apparatus: insulation subassembly |
| 26 | 14 | apparatus: lower heat sink subassembly |
| 28 | 15 | apparatus: upper heat sink subassembly |
| 30 | 3 | apparatus: shaft |
| 32 | 3 | apparatus: linear actuator |
| 34 | 4 | cell holder subassembly: cell-contacting member |
| 36 | 6 | cell-contacting member: lower portion |
| 38 | 8 | cell-contacting member: upper portion |
| 40 | 6 | cell-contacting member: cell-contacting surface |
| | | lower portion |
| 41 | 6 | cell holder subassembly: lower temperature sensor |
| 42 | 8 | cell-contacting member: cell-contacting surface |
| | | upper portion |
| 43 | 8 | cell holder subassembly: upper temperature sensor |
| 44 | 5 | cell holder subassembly: lower Peltier module- |
| | | contacting surface |
| 45 | 6 | cell holder subassembly: lower heat flux sensor |
| 46 | 4 | cell holder subassembly: upper Peltier module- |
| | | contacting surface |
| 47 | 8 | cell holder subassembly: upper heat flux sensor |
| 48 | 6 | cell holder subassembly: positive terminal |
| 49 | 6 | cell holder subassembly: positive terminal block |
| 50 | 6 | cell holder subassembly: positive lead |
| 52 | 6 | cell holder subassembly: wire |
| 54 | 7 | cell holder subassembly: negative terminal |
| 55 | 7 | cell holder subassembly: negative terminal block |
| 56 | 7 | cell holder subassembly: negative lead |
| 58 | 7 | cell holder subassembly: wire |
| 60 | 2 | apparatus: 8-pin female connector |
| 61 | 2 | apparatus: DB9 connector |
| 62 | 2 | apparatus: 8-pin female connector |
| 63 | 2 | apparatus: DB9 connector |
| 64 | 10 | insulation subassembly: housing |
| 66 | 12 | insulation subassembly: housing lower portion |
| 68 | 13 | insulation subassembly: housing upper portion |
| 70 | 11 | insulation subassembly: housing lower portion, |
| | | lower aperture |
| 72 | 10 | insulation subassembly: housing upper portion, |
| | | upper aperture |
| 74 | 12 | insulation subassembly: foam sheet |
| 76 | 11 | insulation subassembly: linear ball bearing assembly |
| 80 | 14 | lower heat sink assembly: bracket |
| 82 | 14 | lower heat sink assembly: bracket, socket |
| 84 | 14 | lower heat sink assembly: Peltier module |
| 86 | 16 | lower heat sink assembly: heat sink member |
| 88 | 14 | lower or upper heat sink assembly: fan assembly |
| 90 | 14 | fan assembly: fan |
| 92 | 14 | fan assembly: fan bracket |
| 94 | 14 | fan assembly: fan guard |
| 100 | 15 | upper heat sink assembly: bracket |
| 102 | 15 | upper heat sink assembly: bracket, socket |
| 104 | 15 | upper heat sink assembly: Peltier module |
| 106 | 17 | upper heat sink assembly: heat sink member |
| 110 | 20 | system |
| 112 | 20 | system: electrical power supply |
| 114 | 20 | system: controller |
| 116 | 20 | controller: processor |
| 118 | 20 | controller: memory |

1. An apparatus for testing an electrochemical cell comprising a pair of cell terminals and a cell casing extending in a longitudinal direction between cell ends, the apparatus comprising:
a pair of terminals positioned to contact the pair of cell terminals;
a cell-contacting member comprising a cell-contacting surface shaped to contact at least part of the cell casing when the pair of cell terminals contact the pair of terminals;
at least one Peltier module comprising a cold side and a hot side, wherein the cold side is in contact with the cell-contacting member; and
at least one heat sink member in contact with the hot side of the at least one Peltier module.

2. The apparatus of claim 1, wherein the cell-contacting surface comprises at least a portion of concave cylindrical surface.

3. The apparatus of claim 1, wherein the cell-contacting surface of the cell-contacting member surrounds the cell casing in a plane transverse to the longitudinal direction.

4. The apparatus of claim 1, wherein the cell-contacting member comprises a plurality of cell-contacting member portions that are separable from each other.

5. The apparatus of claim 1, wherein the cell-contacting member is made of a metal.

6. The apparatus of claim 5, wherein the metal is aluminum.

7. The apparatus of claim 1, wherein the at least one Peltier module comprises a first plurality of Peltier modules spaced apart in a direction transverse to the longitudinal direction.

8. The apparatus of claim 1, wherein the at least one Peltier module comprises a second plurality of Peltier modules spaced apart in the longitudinal direction.

9. The apparatus of claim 1, wherein the at least one heat sink member comprises a plurality of fins.

10. The apparatus of claim 1, wherein the at least one heat sink member comprises a plurality of heat sink members.

11. The apparatus of claim 1, further comprising:
at least one electrical fan oriented to create an air flow across the at least one heat sink member.

12. The apparatus of claim 1, wherein:
the cell-contacting member comprises a cell-contacting member first portion comprising a cell-contacting surface first portion, and a cell-contacting member second portion comprising a cell-contacting surface second portion;
wherein the cell-contacting member first portion is slidably attached to the cell-contacting member second portion to allow a distance between the cell-contacting surface first portion and the cell-contacting surface second portion to be varied.

13. The apparatus of claim 12, further comprising:
at least one linear actuator having an actuator first end attached to the cell-contacting member first portion and an actuator second end attached to the cell-contacting member second portion, and extendible between the actuator first end and the actuator second end to vary the distance between the cell-contacting surface first portion and the cell-contacting surface second portion.

14. The apparatus of claim 1, further comprising:
at least one temperature sensor positioned to measure a temperature of the cell when the pair of cell terminals contact the pair of terminals.

15. The apparatus of claim 1, further comprising:
at least one heat flux sensor positioned to measure a heat flux of the cell when the pair of cell terminals contact the pair of terminals.

16. A system for testing an electrochemical cell comprising a pair of cell terminals and a cell casing extending in a longitudinal direction between cell ends, the system comprising:
an apparatus according to claim 1;
at least one electrical power supply operatively connected to the at least one Peltier module of the apparatus; and
a controller operatively connected to the electrical power supply, and comprising a processor and a memory comprising a non-transitory computer readable medium storing instructions executable by the processor to control a supply of electrical power from the at least one electrical power supply to the at least one Peltier module of the apparatus.

17. The system of claim 16, wherein:
the at least one Peltier module of the apparatus comprises a first Peltier module and a second Peltier module spaced apart from the first Peltier module in the longitudinal direction of the cell; and
the instructions are executable by the processor to control the supply of electrical power from the at least one electrical power supply to the first Peltier module, independently of the supply of electrical power from the at least one electrical power supply to the second Peltier module.

18. The system of claim 16, wherein:
the apparatus comprises a temperature sensor positioned to measure a temperature of the cell; and
the instructions are executable by the processor to control the supply of electrical power from the at least one electrical power supply to the at least one Peltier module of the apparatus based on the temperature of the cell measured by the temperature sensor.

19. The system of claim 16, wherein:
the apparatus comprises a heat flux sensor positioned to measure a heat flux of the cell; and
the instructions are executable by the processor to control the supply of electrical power from the at least one electrical power supply to the at least one Peltier module of the apparatus based on the heat flux of the cell measured by the heat flux sensor.
